(19) United States
(12) Patent Application Publication
(10) Pub. No.: US 2026/0065963 A1
(43) Pub. Date: Mar. 5, 2026

(54) STORAGE DEVICE

(71) Applicant: Kioxia Corporation, Tokyo (JP)

(72) Inventors: Kosuke HATSUDA, Bunkyo Tokyo (JP); Akira KATAYAMA, Yokohama Kanagawa (JP)

(21) Appl. No.: 19/074,275

(22) Filed: Mar. 7, 2025

(30) Foreign Application Priority Data
Aug. 30, 2024 (JP) 2024-149684

(51) Int. Cl. G11C 11/16; H10B 61/00

(52) U.S. Cl. CPC G11C 11/1673; H10B 61/10

(57) ABSTRACT

A storage device includes a memory cell having a magnetoresistance effect element and a switching element connected to the magnetoresistance effect element, a first wiring connected to a first end of the memory cell, a second wiring connected to a second end of the memory cell, a first switch having a third end connected to the second wiring and a fourth end, a third wiring connected to the fourth end, a second switch having a fifth end connected to the third wiring and a sixth end, a fourth wiring connected to the sixth end, a first transistor having a gate connected to the third wiring, a seventh end connected to the fourth wiring and an eighth end, a third switch connected between the eighth end and a first node that receives a first voltage, and a sense amplifier circuit connected to the fourth wiring.

### CROSS-REFERENCE TO RELATED APPLICATION(S)

This application is based upon and claims the benefit of priority from Japanese Patent Application No. 2024-149684, filed Aug. 30, 2024, the entire contents of which are incorporated herein by reference.

### FIELD

Embodiments described herein relate generally to a storage device.

### BACKGROUND

A storage device using a magnetoresistance effect element is known.

### BRIEF DESCRIPTION OF THE DRAWINGS

FIG. 1 illustrates a functional block of a storage device of a first embodiment.

FIG. 2 illustrates a functional block of a core circuit of the storage device of the first embodiment.

FIG. 3 illustrates components of a GWL selector and a GBL selector of the storage device of the first embodiment, and connection between the components.

FIG. 4 illustrates a functional block of a sub-core circuit of the storage device of the first embodiment.

FIG. 5 illustrates components of a WL selector and a BL selector of the storage device of the first embodiment, and connection between the components.

FIG. 6 is a perspective view of a part of a memory cell array of the storage device of the first embodiment.

FIG. 7 illustrates a cross-section of an example of the structure of the memory cell of the storage device of the first embodiment.

FIG. 8 illustrates an example of the voltage and current characteristics of the memory cell of the storage device of the first embodiment.

FIG. 9 illustrates components of a conversion circuit of the storage device of the first embodiment, connection between the components, and related components.

FIG. 10 illustrates an example of components of a read circuit of the storage device of the first embodiment and connection between the components.

FIG. 11 illustrates a layout of a part of the storage device of the first embodiment.

FIG. 12 illustrates several signals and voltage levels of various wirings during data reading of the storage device of the first embodiment with respect to time.

FIG. 13 illustrates components of a sense amplifier circuit of the storage device of a modification of the first embodiment and connection between the components.

FIG. 14 illustrates several signals and voltage levels of various wirings during data reading of the storage device of a second embodiment with respect to time.

FIG. 15 illustrates several signals and voltage levels of various wirings during data reading of the storage device of a third embodiment with respect to time.

### DETAILED DESCRIPTION

Embodiments provide a storage device that can store data with high accuracy.

In general, according to one embodiment, a storage device includes a first memory cell, a first wiring, a second wiring, a first switch, a third wiring, a second switch, a fourth wiring, a first transistor, a third switch, and a sense amplifier circuit. The first memory cell includes a first magnetoresistance effect element, and a first switching element connected to the first magnetoresistance effect element. The first wiring is connected to a first end of the first memory cell. The second wiring is connected to a second end of the first memory cell. The first switch includes a third end connected to the second wiring, and a fourth end. The third wiring is connected to the fourth end. The second switch includes a fifth end connected to the third wiring, and a sixth end. The fourth wiring is connected to the sixth end. The first transistor includes a gate connected to the third wiring, a seventh end connected to the fourth wiring, and an eighth end. The third switch is connected between the eighth end and a first node that receives a first voltage. The sense amplifier circuit is connected to the fourth wiring.

Embodiments will be described below with reference to the drawings. An additional number or character may be added to the end of reference numerals of a plurality of components having the substantially same functions and configurations in a certain embodiment or different embodiments, so as to distinguish between the components. In an embodiment following an embodiment that has already been described, differences from the already described embodiment will be mainly described. All descriptions about a certain embodiment also apply to descriptions of other embodiments unless they are explicitly or obviously excluded.

In this description and the claims, when a certain first element is “connected” to another second element, this means that the first element is connected to the second element directly or via a selectively conductive element (e.g., a transistor).

Hereinafter, embodiments will be described by using a three-dimensional orthogonal coordinate system. The orientation of an x-axis is called an X direction. The orientation opposite to the X direction is called a −X direction. The orientation of a y-axis is called a Y direction. The orientation opposite to the Y direction is called a −Y direction. The orientation of a z-axis is called a Z direction, and an upward direction represents the Z direction. The orientation opposite to the Z direction is called a −Z direction, and a downward direction represents a-Z direction.

### 1. First Embodiment

### 1.1. Configuration (Structure)

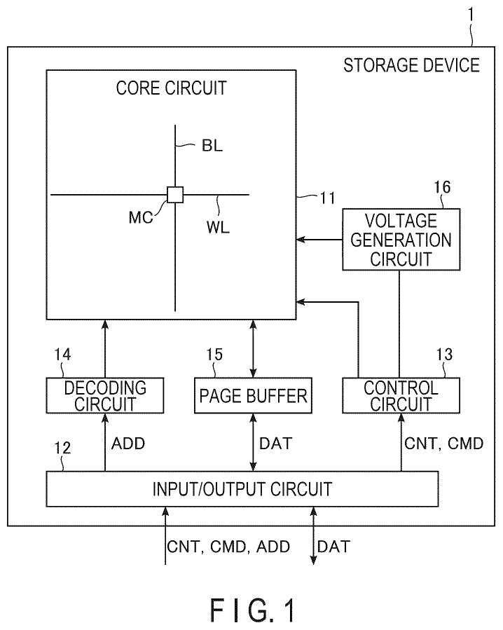

FIG. 1 illustrates a functional block of a storage device of a first embodiment. A storage device 1 includes a core circuit 11, an input/output circuit 12, a control circuit 13, a decoding circuit 14, a page buffer 15, and a voltage generation circuit 16.

The core circuit 11 is a circuit that includes a plurality of memory cells MC, and wirings and circuits for accessing the memory cells MC.

The input/output circuit 12 is a circuit that performs input and output of data and signals. The input/output circuit 12 receives a control signal CNT, a command CMD, address information ADD, and data DAT from the outside of the storage device 1, for example, a memory controller. The input/output circuit 12 outputs the data DAT.

The control circuit 13 receives the command CMD and the control signal CNT from the input/output circuit 12. The control circuit 13 controls the core circuit 11 based on the control instructed by the command CMD and the control signal CNT, and controls reading of data from the memory cells MC, and writing of data to the memory cells MC. The control circuit 13 controls the voltage generation circuit 16 based on the control instructed by the command CMD and the control signal CNT.

The decoding circuit 14 is a circuit that decodes the address information ADD. The decoding circuit 14 receives the address information ADD from the input/output circuit 12. The decoding circuit 14 decodes the address information ADD, and generates, based on the result of the decoding, a signal for selecting the memory cell MC from which data is to be read or to which data is to be written. The generated signal is transmitted to the core circuit 11.

The page buffer 15 is a circuit that temporarily stores data of a certain size. The page buffer 15 receives the data DAT to be written to the memory cell MC from the input/output circuit 12, temporarily stores the data, and transfers the data to the core circuit 11. The page buffer 15 receives the data read from the memory cell MC, temporarily stores the read data, and transfers the data DAT to the input/output circuit 12.

During the writing of the data to the memory cell MC, the voltage generation circuit 16 supplies, to the core circuit 11, the voltage used for the data writing. During the reading of the data from the memory cell MC, the voltage generation circuit 16 supplies, to the core circuit 11, the voltage used for the data reading.

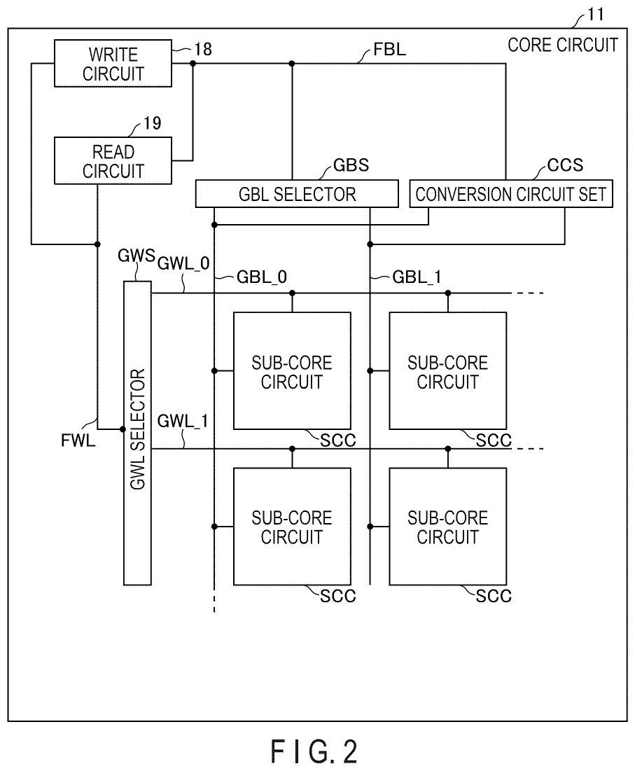

FIG. 2 illustrates a functional block of the core circuit of the storage device of the first embodiment. As illustrated in FIG. 2, the core circuit 11 includes a plurality of sub-core circuits SCC, a plurality of global word lines GWL, a plurality of global bit lines GBL, a GWL selector GWS, a GBL selector GBS, a conversion circuit set CCS, a wiring FWL, a wiring FBL, a write circuit 18, and a read circuit 19.

Each sub-core circuit SCC is a set of a plurality of components, and includes a plurality of memory cells MC, a plurality of selectors, and a plurality of wirings. Each sub-core circuit SCC is connected to one global word line GWL and one global bit line GBL.

Each global word line GWL is connected to the plurality of sub-core circuits SCC. Each global bit line GBL is connected to the plurality of sub-core circuits SCC.

The GWL selector GWS is a circuit that selects one of the plurality of global word lines GWL. Each GWL selector GWS receives the address information ADD or a signal based on the address information ADD, and connects one global word line GWL, which is specified by the received address information ADD or the received signal based on the address information ADD, out of the plurality of global word lines GWL, to the wiring FWL.

The GBL selector GBS is a circuit that selects one of the plurality of global bit lines GBL. Each GBL selector GBS receives the address information ADD or a signal based on the address information ADD, and connects one global bit line GBL, which is specified by the received address information ADD or the received signal based on the address information ADD, out of the plurality of global bit lines GBL, to the wiring FBL.

The conversion circuit set CCS is a set of circuits that convert a current into a voltage. The conversion circuit set CCS is connected between the wiring FBL and the global bit line GBL. The conversion circuit set CCS applies, to the wiring FBL, a voltage whose magnitude is based on the current flowing through the global bit line GBL.

The write circuit 18 is a circuit that controls writing of data to the memory cell MC. The write circuit 18 receives write data DAT from the input/output circuit 12, and receives a voltage for data writing from the voltage generation circuit 16. The write circuit 18 supplies, to the wirings FWL and FBL, the voltage and current to be used for data writing, based on the control by the control circuit 13 and the write data DAT.

The read circuit 19 is a circuit that controls reading of data from the memory cell MC. The read circuit 19 receives the voltage used for data reading from the voltage generation circuit 16. Based on the control by the control circuit 13, the read circuit 19 determines the data stored in the memory cell MC by using the voltage used for data reading. The determined data is supplied to the input/output circuit 12 as read data DAT. The read circuit 19 includes a plurality of sense amplifier circuits SAC. The sense amplifier circuit SAC is a circuit that uses the voltage based on the data stored in the memory cell MC from which the data is to be read, so as to output the data determined to be stored in the memory cell MC from which the data is to be read. The details of the sense amplifier circuit SAC will be described later.

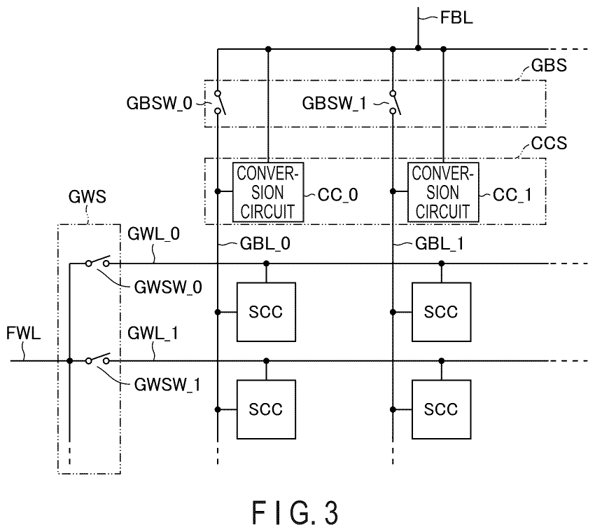

FIG. 3 illustrates components of the GWL selector and the GBL selector of the storage device of the first embodiment, and connection between the components. As illustrated in FIG. 3, the GWL selector GWS includes the same number of switches GWSW as the number of the sub-core circuits SCC connected to each global bit line GBL. Each switch GWSW is connected to the wiring FWL at one end, and to one global word line GWL at the other end. Each of the switches GWSW is a p-type or n-type MOSFET, or the switches GWSW are p-type and n-type MOSFETs that are connected in parallel and that receive complementary signals at respective gates. The description about this switch GWSW also applies to switches GWSW, WSW, BSW, SW1, SW2, SW3, SW4, SW5, SW6, SW11, and SW12, which will be described later. Each switch GWSW is turned ON or OFF under the control of the read circuit 19 or the write circuit 18 based on the address information ADD or the signal based on the address information ADD.

The GBL selector GBS includes the same number of switches GBSW as the number of the sub-core circuits SCC connected to each global word line GWL. Each switch GBSW is connected to the wiring FBL at one end, and to one global bit line GBL at the other end. Each switch GBSW is turned ON or OFF under the control of the read circuit 19 or the write circuit 18 based on the address information ADD or the signal based on the address information ADD.

The conversion circuit set CCS includes the same number of conversion circuits CC as the number of the sub-core circuits SCC connected to each global word line GWL. Each conversion circuit CC is connected between the wiring FBL and one global bit line GBL. Each conversion circuit CC applies, to the global bit line GBL connected to the conversion circuit CC, the voltage whose magnitude is based on the current flowing through the wiring FBL connected to the conversion circuit CC.

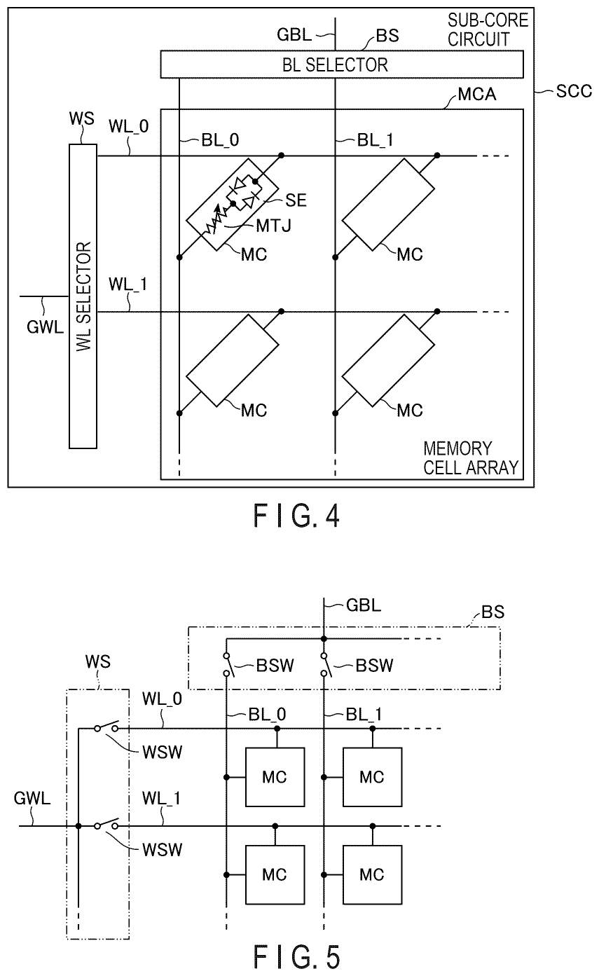

FIG. 4 illustrates a functional block of the sub-core circuit of the storage device of the first embodiment. As illustrated in FIG. 4, each sub-core circuit SCC includes a memory cell array MCA, a plurality of word lines WL, a plurality of bit lines BL, a WL selector WS, a BL selector BS, a global word line GWL, and a global bit line GBL.

The memory cell array MCA is a collection of a plurality of arranged memory cells MC. The memory cell MC can store data in a non-volatile manner. The word lines WL and the bit lines BL are also located in the memory cell array MCA. The following description is based on an example in which the word lines WL are associated with rows, and the bit lines BL are associated with columns. The word lines WL and the bit lines BL are merely the names for distinguishing between two kinds of wirings, and the names may be reversed. Each memory cell MC is connected to one word line WL and one bit line BL. One memory cell MC is specified by selection of one row and selection of one column.

Each word line WL is connected to the plurality of memory cells MC. Each bit line BL is connected to the plurality of memory cells MC. Each memory cell MC includes one MTJ element MTJ and one switching element SE. In each memory cell MC, the MTJ element MTJ and the switching element SE are connected in series. The switching element SE of each memory cell MC is connected to one word line WL. The MTJ element MTJ of each memory cell MC is connected to one bit line BL.

The MTJ element MTJ is an element that exhibits the tunneling magnetoresistive effect, and includes, for example, a magnetic tunnel junction (MTJ). The MTJ element MTJ is also referred to as the magnetoresistance effect element MTJ. The MTJ element MTJ is a variable resistance element capable of switching between a low resistance state and a high resistance state. The MTJ element MTJ can store 1-bit data by utilizing the difference between the two resistance states. In one example, the MTJ element MTJ is considered to store “0” data when in the low resistance state, and to store “1” data when in the high resistance state.

The switching element SE is an element that includes two terminals, and performs electrical connection or disconnection between the two terminals. When the voltage applied between the two terminals in a first direction is less than a certain threshold voltage, the switching element SE is in the high resistance state, for example, an electrically non-conductive state (OFF state). When the voltage applied between the two terminals increases, and becomes equal to or more than the threshold voltage, the switching element SE is in the low resistance state, for example, an electrically conductive state (ON state). When the voltage applied between the two terminals of the switching element SE in the low resistance state decreases, and becomes less than the threshold voltage, the switching element SE goes into the high resistance state again. The switching element SE has the function of switching between the high resistance state and the low resistance state based on the magnitude of the voltage applied in both the first direction as described above and a second direction, which is opposite to the first direction. That is, the switching element SE is a bidirectional switching element. By turning ON or OFF the switching element SE, it is possible to control whether or not to supply a current to the MTJ element MTJ connected to this switching element SE, that is, whether or not to select the MTJ element MTJ.

Each WL selector WS is a circuit that selects one of the plurality of word lines WL. Each WL selector WS receives the address information ADD or the signal based on the address information ADD, and connects, to one global word line GWL, one word line WL specified by the received address information ADD or the received signal based on the address information ADD, out of the plurality of word lines WL.

Each BL selector BS is a circuit that selects one of the plurality of bit lines BL. Each BL selector BS receives the address information ADD or the signal based on the address information ADD, and connects, to one global bit line GBL, one bit line BL specified by the received address information ADD or the received signal based on the address information ADD, out of the plurality of bit lines BL.

FIG. 5 illustrates components of the WL selector and the BL selector of the storage device of the first embodiment, and connection between the components. As illustrated in FIG. 5, the WL selector WS includes same number of switches WSW as the number of the memory cells MC connected to each bit line BL. Each switch WSW is connected to the global word line GWL at one end, and to one word line WL at the other end. Each switch WSW is turned ON or OFF under the control of the read circuit 19 based on the address information ADD or the signal based on the address information ADD.

The BL selector BS includes the same number of switches BSW as the number of the memory cells MC connected to each word line WL. Each switch BSW is connected to the global bit line GBL at one end, and to one bit line BL at the other end. Each switch BSW is turned ON or OFF under the control of the read circuit 19 based on the address information ADD or the signal based on the address information ADD.

In the examples of FIG. 2, FIG. 3, FIG. 4, and FIG. 5, the core circuit 11 includes two layers. A bottom first layer includes the configuration illustrated in FIG. 4, that is, a set of the memory cells MC, the word lines WL, the bit lines BL, the WL selector WS, and the BL selector BS. A second layer includes the configuration illustrated in FIG. 2, that is, a set of the sub-core circuits SCC, the global word lines GWL, the global bit lines GBL, the GWL selector GWS, and the GBL selector GBS.

The core circuit 11 may include three or more layers. When switches of the selectors in each layer are turned ON, one word line WL is connected to the write circuit 18 and the read circuit 19. Similarly, when switches of the selectors in each layer are turned ON, one bit line BL is connected to the write circuit 18 and the read circuit 19.

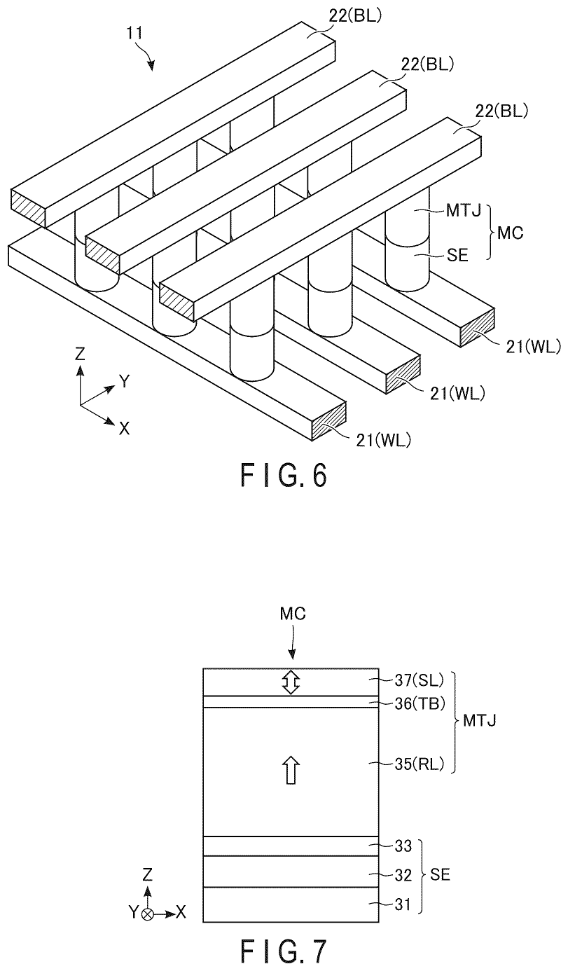

FIG. 6 is a perspective view of a part of the memory cell array of the storage device of the first embodiment. As illustrated in FIG. 6, a plurality of conductors 21 and a plurality of conductors 22 are provided.

The conductors 21 have linear shapes, extend in the X direction, and are arranged in the Y direction. Each conductor 21 functions as at least a part of one word line WL.

The conductors 22 are located further in the Z direction than the conductors 21. The conductors 22 have linear shapes, extend in the Y direction, and are arranged in the X direction. Each conductor 22 functions as at least a part of one bit line BL.

One memory cell MC is provided in each of the intersections of the conductors 21 and the conductors 22. The memory cells MC are arranged in a matrix along an xy plane consisting of the X direction and the Y direction. Each memory cell MC includes a structure that functions as the switching element SE, and a structure that functions as the MTJ element MTJ. Each of the structure that functions as the switching element SE and the structure that functions as the MTJ element MTJ includes one or more layers. For example, the structure that functions as the MTJ element MTJ is located on an upper surface of the structure that functions as the switching element SE. A lower surface of the memory cell MC is in contact with an upper surface of one conductor 21. An upper surface of the memory cell MC is in contact with a lower surface of one conductor 22.

FIG. 7 illustrates a cross-section of an example of the structure of the memory cell of the storage device of the first embodiment. The switching element SE includes a variable resistance material 32. The variable resistance material 32 is a material that exhibits dynamically variable resistance, and has, for example, the shape of a layer. The variable resistance material 32 is a two-terminal switching element, a first terminal of two terminals is one of an upper surface and a lower surface of the variable resistance material 32, and a second terminal of the two terminals is the other of the upper surface and the lower surface of the variable resistance material 32. When the voltage applied between the two terminals is less than a certain threshold voltage, the variable resistance material is in a “high resistance” state, for example, an electrically non-conductive state. When the voltage applied between the two terminals increases, and becomes equal to or more than the threshold voltage, the variable resistance material is in a “low resistance” state, for example, an electrically conductive state. When the voltage applied between the two terminals of the variable resistance material 32 in the low resistance state decreases, and becomes less than the threshold voltage, the variable resistance material goes into the high resistance state again.

In an example, the variable resistance material 32 includes an insulator, and a dopant introduced into the insulator by ion implantation. The insulator includes, for example, an oxide, and includes SiO₂ or a material substantially consisting of SiO₂. In an example, the dopant includes arsenic (As) and germanium (Ge). The phrase “substantially consisting of (or composed of)” and similar phrases mean that a component that is introduced immediately after the phrase “substantially consisting of” is permitted to contain unintended impurities.

The switching element SE may further include a lower electrode 31 and an upper electrode 33. FIG. 7 illustrates such an example. The variable resistance material 32 is located on an upper surface of the lower electrode 31, and the upper electrode 33 is located on the upper surface of the variable resistance material 32.

The MTJ element MTJ includes a ferromagnetic layer 35, an insulating layer 36, and a ferromagnetic layer 37. As an example, as illustrated in FIG. 7, the insulating layer 36 is located on an upper surface of the ferromagnetic layer 35, and the ferromagnetic layer 37 is located on an upper surface of the insulating layer 36.

The ferromagnetic layer 35 is a layer of a material that exhibits ferromagnetism. The ferromagnetic layer 35 has an axis of easy magnetization along a direction penetrating interfaces between the ferromagnetic layer 35, the insulating layer 36, and the ferromagnetic layer 37, has the axis of easy magnetization at an angle of 45 degrees or more and 90 degrees or less with respect to the interfaces in one example, and has the axis of easy magnetization along a direction orthogonal to the interfaces in another example. The direction of magnetization of the ferromagnetic layer 35 remains unchanged irrespective of whether data is read from or written to the memory cell MC. The ferromagnetic layer 35 can function as a so-called reference layer RL. The ferromagnetic layer 35 may include a plurality of layers. Hereinafter, the ferromagnetic layer 35 may be referred to as the reference layer RL.

The insulating layer 36 is a layer of an insulator. The insulating layer 36 includes, for example, magnesium oxide (MgO) or is substantially composed of MgO, and functions as a so-called tunnel barrier (TB).

The ferromagnetic layer 37 is a layer of a material that exhibits ferromagnetism. The ferromagnetic layer 37 includes, for example, cobalt iron boron (CoFeB) or iron boride (FeB), or is substantially composed of CoFeB or FeB. The ferromagnetic layer 37 has an axis of easy magnetization along a direction penetrating the interfaces between the ferromagnetic layer 35, the insulating layer 36, and the ferromagnetic layer 37, has the axis of easy magnetization at an angle of 45 degrees or more and 90 degrees or less with respect to the interfaces in one example, and has the axis of easy magnetization along a direction orthogonal to the interfaces in another example. The direction of magnetization of the ferromagnetic layer 37 is variable by data writing to the memory cell MC, and the ferromagnetic layer 37 can function as a so-called storage layer (SL). Hereinafter, the ferromagnetic layer 37 may be referred to as the storage layer SL.

When the direction of magnetization of the storage layer SL is parallel to the direction of magnetization of the reference layer RL, the MTJ element MTJ has a certain low resistance. When the direction of magnetization of the storage layer SL is antiparallel to the direction of magnetization of the reference layer RL, the MTJ element MTJ has a resistance higher than resistance in the case where the direction of magnetization of the storage layer SL is parallel to the direction of magnetization of the reference layer RL.

When a current equal to or higher than a current Icp with a certain magnitude flows from the storage layer SL toward the reference layer RL, the direction of magnetization of the storage layer SL becomes parallel to the direction of magnetization of the reference layer RL. When a current equal to or higher than a current Icap with a certain magnitude flows from the reference layer RL toward the storage layer SL, the direction of magnetization of the storage layer SL becomes antiparallel to the direction of magnetization of the reference layer RL.

The MTJ element MTJ may include a further layer.

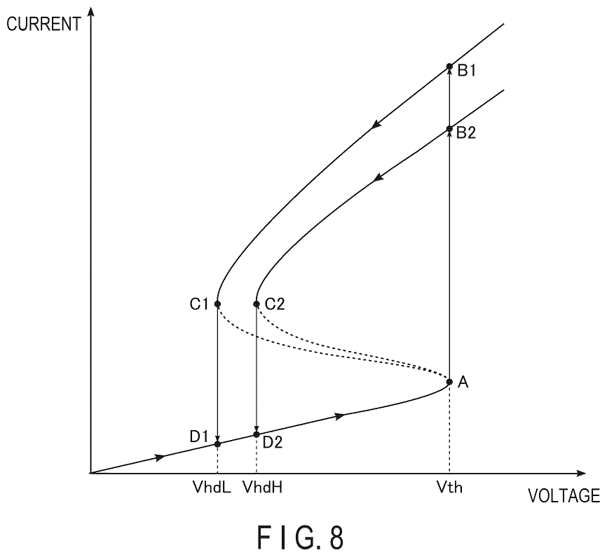

FIG. 8 illustrates an example of the voltage and current characteristics of the memory cell of the storage device of the first embodiment. A horizontal axis of a graph represents the magnitude of a terminal voltage (that is, the difference in voltage between both ends) of the memory cell MC. A vertical axis of the graph represents the magnitude of a current flowing through the memory cell MC on a logarithmic scale. FIG. 8 illustrates virtual characteristics that do not actually appear by broken lines. FIG. 8 illustrates a case where the memory cell MC is in the low resistance state and a case where the memory cell MC is in the high resistance state.

When the voltage is increased from 0, the current continues increasing until the voltage reaches a threshold voltage Vth. Until the voltage reaches the threshold voltage Vth, the switching element SE of the memory cell MC is turned OFF, that is, non-conductive.

When the voltage is further increased, and the voltage reaches the threshold voltage Vth, that is, when the voltage reaches a point A, the relationship between the voltage and the current exhibits discontinuous changes, and exhibits characteristics indicated by a point B1 and a point B2. The magnitude of the current at the point B1 and the point B2 is significantly greater than the magnitude of the current at the point A. This rapid change in the current occurs because the switching element SE of the memory cell MC is turned ON. The magnitude of the current at the point B1 and the point B2 depends on the resistance state of the MTJ element MTJ of the memory cell MC.

When the voltage is decreased from the state where the switching element SE is turned ON, for example, the state where the relationship between the voltage and the current is illustrated at the point B1 or the point B2 and a point of a voltage higher than them, the current continues decreasing.

When the voltage is further decreased and reaches a certain magnitude, the relationship between the voltage and the current exhibits discontinuous changes. The voltage at which the relationship between the voltage and the current begins to exhibit discontinuity depends on the terminal voltage of the MTJ element MTJ of the memory cell MC, that is, depends on whether the MTJ element MTJ is in the high resistance state or the low resistance state. When the MTJ element MTJ is in the low resistance state, the relationship between the voltage and the current exhibits discontinuity from a point C1. When the MTJ element MTJ is in the high resistance state, the relationship between the voltage and the current exhibits discontinuity from a point C2. When the relationship between the voltage and the current reaches the point C1 and the point C2, the relationship exhibits the characteristics indicated by a point D1 and a point D2, respectively. The magnitude of the current at the point D1 and the point D2 is significantly smaller than the magnitude of the current at the point C1 and the point C2, respectively. This rapid change in the current occurs because the switching element SE of the memory cell MC is turned OFF.

The terminal voltage at the point D1 of the memory cell MC including the MTJ element MTJ in the low resistance state is referred to as a low hold voltage VhdL. The terminal voltage at the point D2 of the memory cell MC including the MTJ element MTJ in the high resistance state is referred to as a high hold voltage VhdH.

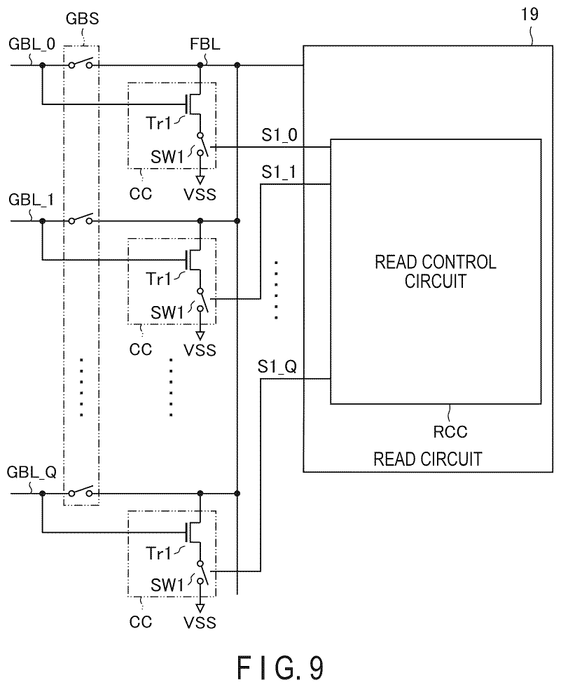

FIG. 9 illustrates components of the conversion circuit of the storage device of the first embodiment, connection between the components, and related components. FIG. 9 illustrates an example of Q+1 global bit lines GBL_0 to GBL_Q.

Each conversion circuit CC includes an n-type MOSFET Tr1 and a switch SW1. The transistor Tr1 and the switch SW1 are connected in series between the wiring FBL and a node that receives a ground voltage VSS. The transistor Tr1 is connected to one global bit line GBL at a gate thereof. A switch SW1_0 receives a signal S1_0. The switch SW1_0 is turned ON or OFF by the signal S1_0. Similarly, in all cases where α is an integer of one or more and Q or less, a switch SW1_α receives a signal S1_α. The switch SW1_α is turned ON or OFF by the signal S1_α. Signals S1_0 to S1_Q are supplied from a read control circuit RCC. The read control circuit RCC is included in the read circuit 19.

While receiving a high level or “H” level signal S1, the switch SW1 is in an ON state, and maintains a state where one end and the other end of the switch SW1 are electrically connected. While receiving a low level or “L” level signal S1, the switch SW1 is in an OFF state, and maintains a state where the one end and the other end of the switch SW1 are electrically disconnected.

The same applies to a switch SWn and a signal Sn, which will be described later, where n is an integer of two or more. That is, the description for the switch SW1 is applied to the switch SWn by replacing the switch SW1 with the switch SWn in the description, and the description for the signal S1 is applied to the signal Sn by replacing the signal S1 with the signal Sn in the description.

For all the cases where α is an integer of 0 or more and Q or less, during data reading and when the address information ADD specifies a global bit line GBL_α, the read control circuit RCC maintains the signal S1_α at the high level.

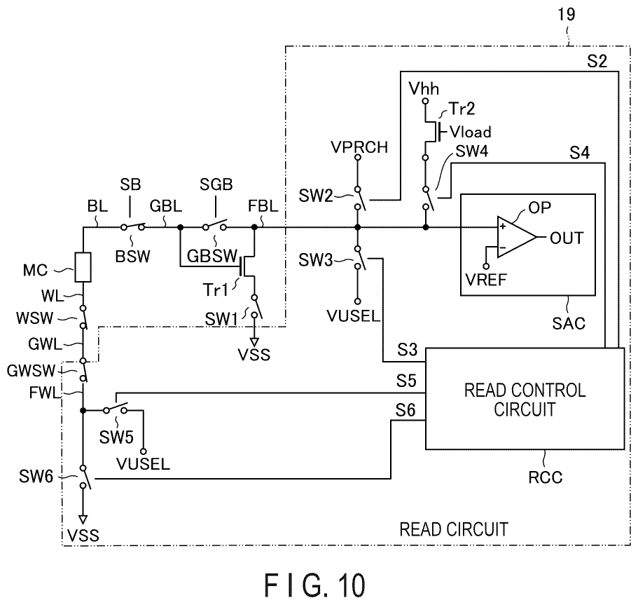

FIG. 10 illustrates an example of components of the read circuit of the storage device of the first embodiment and connection between the components. FIG. 10 also illustrates, as a representative, one memory cell MC from which data is to be read, and components related to this memory cell MC. Hereinafter, the memory cell MC from which data is to be read or to which data is to be written may be referred to as the selected memory cell MC_s.

The switch GBSW for connecting the selected memory cell MC_s to the wiring FBL is referred to as a switch GBSW_s. A signal received by the switch GBSW at a control terminal may be referred to as a signal SGB, and a signal received by the switch GBSW_s at a control terminal may be referred to as a signal SGB_s.

The read circuit 19 further includes switches SW2, SW3, SW4, SW5, and SW6, an n-type MOSFET Tr2, and a sense amplifier circuit SAC.

The switch SW2 is connected between a node that receives a precharge voltage VPRCH and the wiring FBL. In an example, the precharge voltage VPRCH is supplied from the voltage generation circuit 16. The precharge voltage VPRCH is higher than the ground voltage VSS.

The switch SW3 is connected between the wiring FBL and a node that receives a non-selection voltage VUSEL with a constant magnitude. In one example, the non-selection voltage VUSEL is supplied from the voltage generation circuit 16. The non-selection voltage VUSEL has a level between the ground voltage VSS and the precharge voltage VPRCH. In another example, the non-selection voltage VUSEL has half the level of the precharge voltage VPRCH.

The transistor Tr2 is connected, at one end, to a node that receives a voltage Vhh of a constant positive level. In one example, the voltage Vhh is an internal power supply voltage of the storage device 1, and is lower than a power supply voltage VDD. In another example, the voltage Vhh is supplied from the voltage generation circuit 16. The transistor Tr2 receives a voltage Vload with a constant positive level at a gate thereof, and the voltage Vload is higher than the ground voltage VSS. In one example, the voltage Vload is supplied from the voltage generation circuit 16. The transistor Tr2 supplies, at the other end, a constant current with a magnitude based on the magnitude of the voltages Vhh and Vload.

The switch SW4 is connected between the other end of the transistor Tr2 and the wiring FBL.

The sense amplifier circuit SAC outputs data OUT determined to be stored in the selected memory cell MC_s from which data is to be read, based on the supplied voltage. In an example, the sense amplifier circuit SAC includes an operational amplifier OP. A non-inverting input of the operational amplifier OP is connected to the wiring FBL. An inverting input of the operational amplifier OP receives a voltage VREF with a constant magnitude. In an example, the voltage VREF has a level between a high hold voltage VhdH and a low hold voltage VhdL.

The switch SW5 is connected between the wiring FWL and a node that receives the non-selection voltage VUSEL. The switch SW6 is connected between the wiring FWL and a node that receives the ground voltage VSS.

The read control circuit RCC outputs signals S2, S3, S4, S5 and S6.

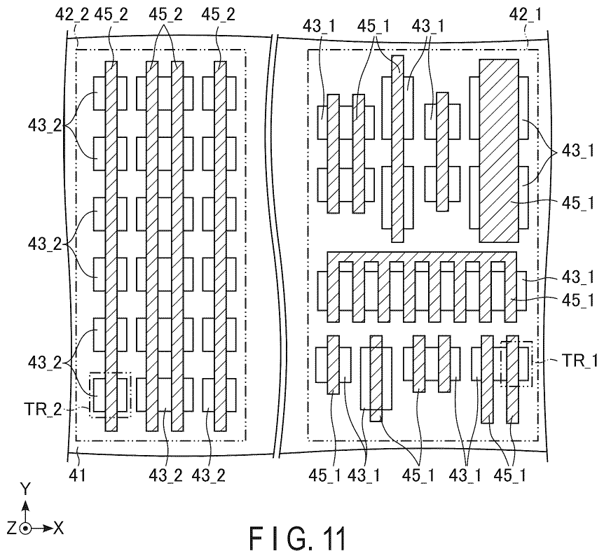

FIG. 11 illustrates a layout of a part of the storage device of the first embodiment. As illustrated in FIG. 11, the storage device 1 includes a substrate 41. The substrate 41 extends along the xy plane. The storage device 1 includes an area 42_1 and an area 42_2.

The area 42_1 includes a plurality of source/drain areas 43_1 and a plurality of conductors 45_1. The source/drain areas 43_1 have various dimensions and shapes. The conductors 45_1 have various dimensions and shapes. The source/drain areas 43_1 are irregularly arranged. Each source/drain area 43_1 and a portion of the conductor 45_1 that overlaps with this source/drain area 43_1 functions as a transistor TR_1. In one example, the transistor TR_1 corresponds to a transistor in the sense amplifier circuit SAC.

The area 42_2 includes a plurality of source/drain areas 43_2 and a plurality of conductors 45_2. The source/drain areas 43_2 and the conductors 45_2 are regularly arranged. In the example of FIG. 11, the source/drain areas 43_2 have the same dimensions, or dimensions isotropically scaled from the dimensions of a certain reference, and are arranged in a matrix. The conductors 45_2 are also regularly arranged. In the example of FIG. 11, the conductors 45_2 have the same dimension in the Y direction, and are arranged in the X direction.

Each source/drain area 43_2 and a portion of the conductor 45_2 that overlaps with this source/drain area 43_2 functions as a transistor TR_2. In one example, the transistor TR_2 corresponds to a transistor of the switches GWSW, GBSW, WSW, and BSW. In addition, in another example, the transistor TR_2 corresponds to the transistor Tr1 and a transistor of the switch SW1. That is, the conversion circuit CC is located in the area 42_2.

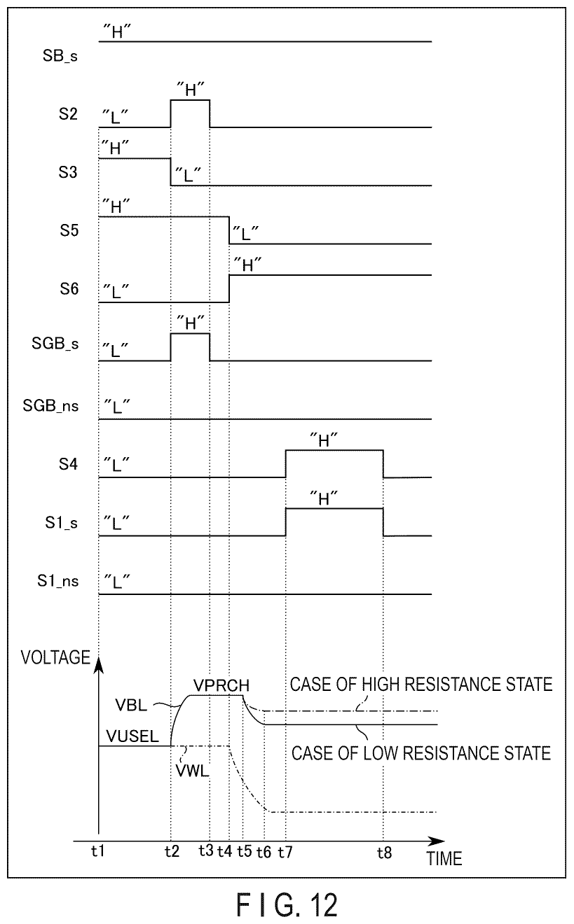

The area 42_2 has an arrangement different from that of the area 42_1 in that it does not include source/drain areas and conductors having irregular shapes and dimensions. 1.2. Operation FIG. 12 illustrates several signals and voltage levels of various wirings wiring during data reading of the storage device of the first embodiment with respect to time. FIG. 12 illustrates a state where one selected memory cell MC_s from which data is to be read is selected. That is, the switches BSW, WSW, and GWSW connected to the selected memory cell MC_s are turned ON during a time period illustrated in FIG. 12. The operation in the time period illustrated in FIG. 12 is started when data reading is started in a state where the selected memory cell MC_s from which data is to be read is selected.

The selected memory cell MC_s from which data is to be read is selected over the time period illustrated in FIG. 12, and for that purpose, a signal SB_s has a high level over the time period illustrated in FIG. 12. The signal SB_s is a signal that turns ON or OFF the switch BSW connected to a selected bit line BL_s. The selected bit line BL_s is the bit line BL connected to the selected memory cell MC_s. With the high level signal SB_s, the selected bit line BL_s is connected to one global bit line GBL via the switch BSW that is turned ON, over the time period illustrated in FIG. 12. Hereinafter, the global bit line GBL connected to the selected bit line BL_s via the switch BSW that is turned ON may be referred to as the selected global bit line GBL_s.

A signal SGB_ns has a low level over the time period illustrated in FIG. 12. The signal SGB_ns is a signal that turns ON or OFF a switch GBSW_ns connected to the global bit line GBL other than the selected global bit line GBL_s. The signal SB_s is depicted as the signal SB in FIG. 10. Hereinafter, the global bit line GBL other than the selected global bit line GBL_s may be referred to as the non-selected global bit line GBL_ns. With the low level signal SGB_ns, the switch GBSW_ns is turned OFF, and therefore, the non-selected global bit line GBL_ns is disconnected from the wiring FBL over the time period illustrated in FIG. 12.

A signal S1_ns has a low level over the time period illustrated in FIG. 12. The signal S1_ns is the signal S1 supplied to the switch SW1 in the conversion circuit CC connected to the non-selected global bit line GBL_ns.

At a time t1, a signal S1_s has a low level. The signal S1_s is the signal S1 supplied to the switch SW1 in the conversion circuit CC connected to the selected global bit line GBL_s. With the low level signal S1_s, the switch SW1 in the conversion circuit CC connected to the selected global bit line GBL_s is turned OFF.

At the time t1, the signals S2, S4, and S6 have a low level, and the signals S3 and S5 have a high level. Hence, the switches SW2, SW4, and SW6 are turned OFF, and the switches SW3 and SW5 are turned ON.

At the time t1, the signal SGB_s has a low level. The signal SGB_s is a signal for turning ON or OFF the switch GBSW_s connected to the global bit line GBL connected to the switch BSW that is turned ON. With the low level signal SGB_s, the switch GBSW_s is turned OFF.

Based on the fact that the switch SW2 is turned OFF and the switch SW3 is turned ON, the wiring FBL receives the non-selection voltage VUSEL, and therefore, a voltage (selected bit line voltage) VBL of the selected bit line BL_s has a non-selection voltage VUSEL.

Based on the fact that the switch SW6 is turned OFF and the switch SW5 is turned ON, the wiring FWL receives the non-selection voltage VUSEL, and therefore, the voltage (selected word line voltage) VWL of the word line (selected word line) WL connected to the selected memory cell MC_s has the non-selection voltage VUSEL.

At a time t2, the signal SGB_s is at a high level. Accordingly, the selected global bit line GBL_s is connected to the wiring FBL.

At the time t2, the signal S2 is at a high level, and the signal S3 is at a low level. Accordingly, the switch SW2 is turned ON, and the switch SW3 is turned OFF. Therefore, from the time t2, the selected bit line voltage VBL increases and reaches the precharge voltage VPRCH.

At a time t3, the signal S2 is at the low level. Accordingly, the switch SW2 is turned OFF, and the wiring FBL, the selected global bit line GBL_s, and the selected bit line BL_s are electrically floating. Even after the time t3, the selected bit line voltage VBL remains at the precharge voltage VPRCH.

At the time t3, the signal SGB_s is at the low level. Accordingly, the switch GBSW_s is turned OFF, and the selected global bit line GBL_s is disconnected from the wiring FBL.

At a time t4, the signal S5 is at a low level, and the signal S6 is at a high level. Accordingly, the switch SW5 is turned OFF, and the switch SW6 is turned ON. Therefore, the selected word line voltage VWL falls toward a ground voltage VSS.

At a time t5, the difference between the selected word line voltage VWL and the selected bit line voltage VBL reaches the threshold voltage Vth. Accordingly, the switching element SE of the selected memory cell MC_s is turned ON. Therefore, the selected word line WL is electrically connected to the selected bit line BL_s via the turned-on switching element SE in the selected memory cell MC_s. Accordingly, a cell current flows from the selected bit line BL_s toward the selected word line WL.

Since the selected bit line BL_s is electrically floating, the selected bit line voltage VBL falls when the cell current flows. At this time, the selected bit line voltage VBL falls at a different speed, based on the state of the MTJ element MTJ of the selected memory cell MC_s. The selected bit line voltage VBL in the case where the MTJ element MTJ of the selected memory cell MC_s is in the high resistance state falls more slowly than the fall of the selected bit line voltage VBL in the case where the MTJ element MTJ of the selected memory cell MC_s is in the low resistance state.

At a time t6, the selected bit line voltage VBL drops to a level that is based on the resistance state of the MTJ element MTJ of the selected memory cell MC_s. That is, as the selected bit line voltage VBL falls, the difference between the selected bit line voltage VBL and the selected word line voltage VWL decreases. Accordingly, when the terminal voltage of the selected memory cell MC_s reaches a certain level, the switching element SE of the selected memory cell MC_s is turned OFF. As a result, the fall of the selected bit line voltage VBL stops, and the selected bit line voltage VBL stabilizes to a certain level.

With the operation from the time t4 to the time t6, not only the selected bit line voltage VBL but also the selected global bit line GBL_s reaches a voltage based on the state of the selected memory cell MC_s. Hereinafter, the operation from the time t4 to the time t6 may be referred to as the signal output operation.

At a time t7, the signals S4 and S1_s are at high levels. Accordingly, the switch SW1 and the switch SW4 are turned ON, and a constant current is applied to the wiring FBL. At the time point of the time t7, the selected global bit line GBL_s has a voltage according to the state of the selected memory cell MC_s, and therefore, the voltage that is based on the state of the selected memory cell MC_s is applied to the gate of the transistor Tr1. Hence, the voltage of the wiring FBL reaches the voltage that is based on the state of the selected memory cell MC_s. In this manner, the cell current with a magnitude based on the state of the selected memory cell MC_s is converted into a voltage.

Next, the data determined to be stored in the selected memory cell MC_s, which is specified based on the voltage of the wiring FBL, is output from the sense amplifier circuit SAC.

At a time t8, the signals S4 and S1_s are at the low levels. The operation from the time t7 to the time t8 may be referred to as the sense operation.

The signal S1_s may be at a high level during the signal output operation and the sense operation, that is, after the time t4, and at a low level until the time t4.

### 1.3. Advantages (Effects)

According to the first embodiment, as described below, a storage device that has a high operating margin and can accurately stores data, is provided.

As an example for reference, a configuration is conceivable in which an input of the conversion circuit CC, that is, the gate of the transistor Tr1, is connected to the wiring FBL, and an output of the conversion circuit CC, that is, a drain of the transistor Tr1 is connected to the sense amplifier circuit SAC. In this case, the switch GBSW is maintained ON during the signal output operation and the sense operation. As is clear from the above description referring to FIG. 3, since many elements are connected to the wiring FBL via many global bit lines GBL and global bit lines GBL, the parasitic capacitance of the wiring FBL is large. Due to the large parasitic capacitance, a large cell current flows when the switching element SE of the selected memory cell MC_s is turned ON. This can cause read disturb. The read disturb can cause erroneous writing of unintended data to the selected memory cell MC_s, and may destroy the data stored in the selected memory cell MC_s.

In order to suppress the read disturb, the signal output operation may be performed in a state where the selected bit line BL_s is disconnected from the selected global bit line GBL_s or the wiring FBL. Additionally, after a voltage Vout based on the state of the selected memory cell MC_s appears in the selected bit line BL_s due to the signal output operation, the selected bit line BL_s is connected to the selected global bit line GBL_s and the wiring FBL, thereby transferring the charge accumulated in the selected bit line BL_s to the wiring FBL by charge sharing. The sense operation is performed in this state. In this case, since the capacitance of the selected bit line BL_s is small, the charge accumulated in the selected bit line BL_s that has the voltage Vout is small. Therefore, the cell current is suppressed, and the read disturb is suppressed.

According to the first embodiment, the input of the conversion circuit CC is connected to the global bit line GBL, and the output of the conversion circuit CC is connected to the wiring FBL. Additionally, while the selected global bit line GBL_s is disconnected from the wiring FBL, the signal output operation and the sense operation are performed. Since the selected global bit line GBL_s is disconnected from the wiring FBL, during the signal output operation, while the selected bit line BL_s and the selected global bit line GBL_s have the voltage Vout based on the state of the selected memory cell MC_s, the charge accumulated in the selected bit line BL_s and the selected global bit line GBL_s is small. Therefore, the cell current at the time when the switching element SE of the selected memory cell MC_s is turned ON is small. On the other hand, since the selected bit line BL_s and the selected global bit line GBL_s have the voltage Vout based on the state of the selected memory cell MC_s, the output of the conversion circuit CC is large. Therefore, it is possible to achieve highly accurate data storing and a high operating margin.

### 1.4. Modifications

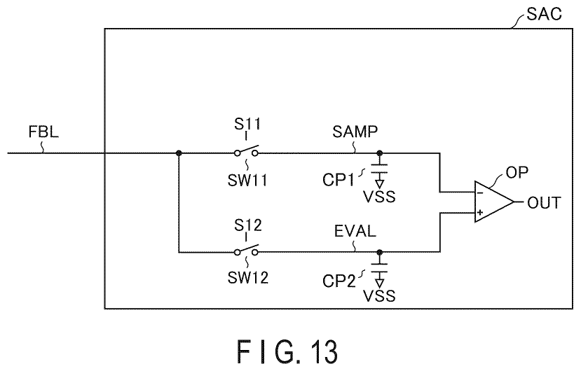

The sense amplifier circuit SAC may have components and connection between the components illustrated in FIG. 13. FIG. 13 illustrates the components of the sense amplifier circuit of the storage device of a modification of the first embodiment and the connection between the components.

As illustrated in FIG. 13, the sense amplifier circuit SAC includes switches SW11 and SW12, capacitors CP1 and CP2, and an operational amplifier OP.

The switch SW11 is connected between the wiring FBL and a node SAMP. In an example, a signal S11 is supplied from the read control circuit RCC.

The capacitor CP1 is connected between the node SAMP and a node that receives the ground voltage VSS.

The switch SW12 is connected between the wiring FBL and a node EVAL. In an example, a signal S12 is supplied from the read control circuit RCC.

The capacitor CP2 is connected between the node EVAL and a node that receives the ground voltage VSS.

The operational amplifier OP is connected to the node SAMP at an inverting input, and is connected to the node EVAL at a non-inverting input.

A read operation of data is as follows. First, in a state where the switch SW11 is turned ON, the operation described above with reference to FIG. 12 is performed. Accordingly, the voltage based on the state of the selected memory cell MC_s appears in the node SAMP. Thereafter, the switch SW11 is turned OFF, and accordingly, the voltage based on the state of the selected memory cell MC_s is saved in the node SAMP. The determination of the data by the sense amplifier circuit SAC after the time t7 of the operation described above with reference to FIG. 12 is not performed.

Fixed reference data determined in advance is written to the selected memory cell MC_s. The reference data may be data “0”, or may be data “1” The following description is based on an example of the data “0”.

In the state where the switch SW12 is turned ON, the operation described above with reference to FIG. 12 is performed. Accordingly, the voltage based on the state of the selected memory cell MC_s appears in the node EVAL. The voltage is based on the reference data of the selected memory cell MC_s. Thereafter, the switch SW12 is turned OFF, and accordingly, the voltage based on the state of the selected memory cell MC_s is saved in the node EVAL. The determination of the data by the sense amplifier circuit SAC after the time t7 of the operation described above with reference to FIG. 12 is not performed.

When the operational amplifier OP is enabled, the data OUT having a value based on the voltage of the node SAMP and the voltage of the node EVAL is output. The data OUT has a value based on the data determined to be stored in the selected memory cell MC_s at the time when data reading is started. In a case where the selected memory cell MC_s stores the data “0” at the time when data reading is started, the data stored in the selected memory cell MC_s at the time when data reading is started and the written reference data are the same. The data OUT having a value that reflects this is output.

On the other hand, in a case where the selected memory cell MC_s stores the data “1” at the time when data reading is started, the data stored in the selected memory cell MC_s at the time when data reading is started and the written reference data are different. The data OUT having a value that reflects this is output.

After the data OUT is output, the data determined to be stored in the selected memory cell MC_s at the time when data reading is started is written to the selected memory cell MC_s.

According to the modification, the voltage based on the state of the selected memory cell MC_s (the voltage of the node SAMP) is compared with the voltage based on known data written in this selected memory cell MC_s (the voltage of the node EVAL), thereby determining the data of the selected memory cell MC_s. Even if the characteristics of the memory cell MC inevitably vary, the influence of the variations is more suppressed than in a case where the voltage based on the state of the selected memory cell MC_s is compared with a certain common voltage.

In addition, the same components with the same functions and different positions (for example, the switches GBSW connected to different global bit lines GBL) may also have the characteristics that are inevitably different. Even when data is read from a plurality of memory cells that store certain identical data, due to variations in the characteristics of the components that are involved in reading of the data of the memory cells MC, the obtained results of reading of the data may be different. According to the modification, the data of the selected memory cell MC_s is determined by comparison between the voltage that is read from the selected memory cell MC_s and the voltage based on the known reference data that is written to the selected memory cell MC_s. Therefore, the component involved in reading of data from the selected memory cell MC_s and the component involved in reading of the written reference data are the same. Therefore, the variance in the results of reading the same data from different memory cells MC due to variations in the characteristics of the plurality of components can be suppressed.

### 2. Second Embodiment

A second embodiment is different from the first embodiment in the operation of data reading.

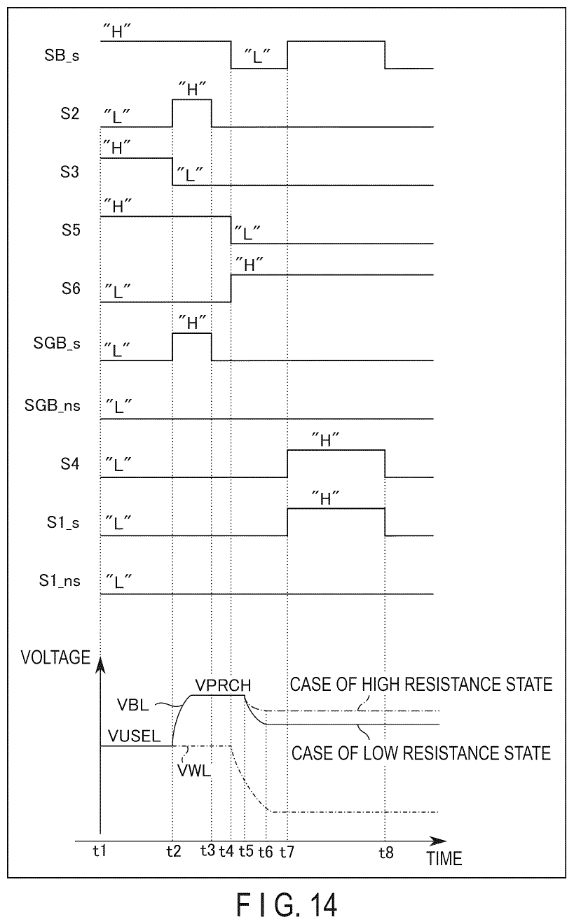

FIG. 14 illustrates several signals and the voltage of a wiring during data reading of the storage device of the second embodiment with respect to time. FIG. 14 illustrates the state where one memory cell MC from which data is to be read is selected, as in FIG. 12 of the first embodiment. The operation in the time period illustrated in FIG. 14 is started when data reading is started in a state where the memory cell MC from which data is to be read is selected.

As illustrated in FIG. 14, at the time t4, the signal SB_s is at the low level. Accordingly, at the time t4, the selected bit line BL_s is disconnected from the selected global bit line GBL_s. Therefore, the signal output operation is performed in a state where the selected bit line BL_s is disconnected from the selected global bit line GBL_s.

At the time t7, the signal SB_s is at the high level. Accordingly, the selected bit line BL_s is connected to the selected global bit line GBL_s. Therefore, the sense operation is performed in a state where the selected bit line BL_s is connected to the selected global bit line GBL_s.

According to the second embodiment, during the signal output operation, the selected bit line BL_s is disconnected from the selected global bit line GBL_s. Therefore, the parasitic capacitance of the wiring (that is, the selected bit line BL_s) connected to the selected memory cell MC_s during the signal output operation is smaller than the parasitic capacitance in the first embodiment. Therefore, the cell current is even smaller.

### 3. Third Embodiment

A third embodiment is performed additionally to the first embodiment.

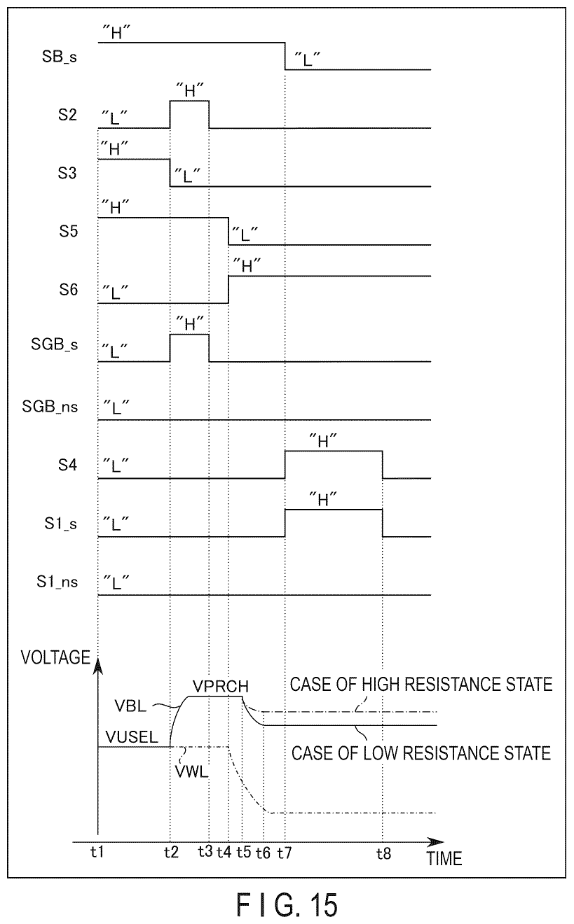

FIG. 15 illustrates several signals and the voltage of a wiring during data reading of the storage device of the third embodiment with respect to time. FIG. 15 illustrates the state where one selected memory cell MC_s from which data is to be read is selected, as in FIG. 12 of the first embodiment. The operation in the time period illustrated in FIG. 15 is started when data reading is started in a state where the selected memory cell MC_s from which data is to be read is selected.

As illustrated in FIG. 15, at the time t7, the signal SB_s is at the low level. Accordingly, the selected bit line BL_s is disconnected from the selected global bit line GBL_s. The disconnection of the selected bit line BL_s from the selected global bit line GBL_s is continued until the end of the time period illustrated in FIG. 15.

According to the third embodiment, as described below, data can be highly accurately read. Even when the switching element SE is turned OFF, a weak leakage current may flow through the switching element SE. Therefore, during data reading, the selected bit line voltage VBL may be decreased after the time (the time t5 in FIG. 15) when the switching element SE of the selected memory cell MC_s is turned OFF. This may lead to decrease in the accuracy of data reading, and (or) decrease in the margin of data reading. According to the third embodiment, after the signal output operation, the selected bit line BL_s is disconnected from the selected global bit line GBL_s. Therefore, the decrease in the charge in the wiring FBL, which is used for the determination of data, due to leakage via the switching element SE after the signal output operation can be suppressed. This leads to suppression of decrease in the accuracy of data reading and (or) the margin of data reading. Even when the amount of charge accumulated in the wiring connected to the selected memory cell MC_s is small due to the signal output operation, decrease in the accuracy of data reading and (or) the margin of data reading is suppressed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A storage device comprising:
a first memory cell including a first magnetoresistance effect element, and a first switching element connected to the first magnetoresistance effect element;
a first wiring connected to a first end of the first memory cell;
a second wiring connected to a second end of the first memory cell;
a first switch including a third end connected to the second wiring, and a fourth end;
a third wiring connected to the fourth end;
a second switch including a fifth end connected to the third wiring, and a sixth end;
a fourth wiring connected to the sixth end;
a first transistor including a gate connected to the third wiring, a seventh end connected to the fourth wiring, and an eighth end;
a third switch connected between the eighth end of the first transistor and a first node that receives a first voltage; and
a sense amplifier circuit connected to the fourth wiring.

2. The storage device of claim 1, further comprising:
a first area including a plurality of first source/drain areas having different shapes and dimensions, and a plurality of first gate electrodes having different shapes and dimensions; and
a second area where a plurality of second source/drain areas arranged in a first direction is repeatedly provided in a second direction, and a plurality of second gate electrodes extending in the second direction and arranged in the first direction, each of the plurality of second gate electrodes provided on one set of the second source/drain areas aligned in the second direction, wherein
the sense amplifier circuit includes one of the plurality of first source/drain areas and at least a part of one of the plurality of first gate electrodes, and
the first transistor includes one of the plurality of second source/drain areas and at least a part of the second gate electrode provided on said one of the plurality of second source/drain areas.

3. The storage device of claim 1, wherein
a time period for reading data from the first memory cell includes a first time period, and
during the first time period, the first switch is maintained ON, the third switch turned ON and then maintained ON, and the second switch maintained OFF.

4. The storage device of claim 3, further comprising:
a second memory cell including a second magnetoresistance effect element, and a second switching element connected to the second magnetoresistance effect element;
a fifth wiring connected to a ninth end of the second memory cell;
a sixth wiring connected to a tenth end of the second memory cell;
a fourth switch including an eleventh end connected to the sixth wiring, and a twelfth end;
a seventh wiring connected to the twelfth end;
a fifth switch including a thirteenth end connected to the seventh wiring, and a fourteenth end connected to the fourth wiring;
a second transistor including a gate connected to the seventh wiring, a fifteenth end connected to the fourth wiring, and a sixteenth end; and
a sixth switch connected between the sixteenth end and a second node that receives the first voltage,
wherein, during the time period for reading, the fourth switch, the fifth switch, and the sixth switch are maintained OFF.

5. The storage device of claim 4, wherein
in a second time period before the first time period, the fourth wiring is caused to be electrically floating after a second voltage is applied, and while the fourth wiring is caused to be electrically floating, a third voltage lower than the second voltage is applied to the first wiring, and
in the first time period, a fourth voltage lower than the third voltage is applied to the first wiring.

6. The storage device of claim 3, wherein
the time period for reading further includes a third time period that starts during the first time period and ends with the first time period, and
during the third time period, the first switch is turned OFF and then maintained OFF, the second switch maintained OFF, and the third switch turned ON and then maintained ON.

7. The storage device of claim 6, wherein
in a second time period before the first time period, the fourth wiring is caused to be electrically floating after a second voltage is applied, and while the fourth wiring is caused to be electrically floating, a third voltage lower than the second voltage is applied to the first wiring, and
in the first time period, a fourth voltage lower than the third voltage is applied to the first wiring.

8. The storage device of claim 1, wherein
a time period for reading data from the first memory cell includes a first time period, and a third time period that starts during the first time period and ends with the first time period,
during the first time period, the first switch is turned OFF, then maintained OFF until a start of the third time period, turned ON at the start of the third time period, and then maintained ON, the second switch maintained OFF, and the third switch turned ON and then maintained ON.

9. The storage device of claim 8, wherein
in a second time period before the first time period, the fourth wiring is caused to be electrically floating after a second voltage is applied, and while the fourth wiring is caused to be electrically floating, a third voltage lower than the second voltage is applied to the first wiring, and
in the first time period, a fourth voltage lower than the third voltage is applied to the first wiring.

10. The storage device of claim 9,
wherein the sense amplifier circuit includes:
a seventh switch connected between the fourth wiring and an eighth wiring;
a first capacitor including an end connected to the eighth wiring;
an eighth switch connected between the fourth wiring and a ninth wiring;
a second capacitor including an end connected to the ninth wiring; and
an operational amplifier including a first input connected to the eighth wiring, and a second input connected to the ninth wiring.

11. A method of reading data in a storage device comprising:
a first memory cell including a first magnetoresistance effect element, and a first switching element connected to the first magnetoresistance effect element;
a first wiring connected to a first end of the first memory cell;
a second wiring connected to a second end of the first memory cell;
a first switch including a third end connected to the second wiring, and a fourth end;
a third wiring connected to the fourth end;
a second switch including a fifth end connected to the third wiring, and a sixth end;
a fourth wiring connected to the sixth end;
a first transistor including a gate connected to the third wiring, a seventh end connected to the fourth wiring, and an eighth end;
a third switch connected between the eighth end of the first transistor and a first node that receives a first voltage; and
a sense amplifier circuit connected to the fourth wiring, said method comprising, during a first time period for reading data from the first memory cell:
maintaining the first switch to be ON;
turning the third switch ON and then maintaining the third switch to be ON; and
maintaining the second switch to be OFF.

12. The method of claim 11, wherein the storage device further comprises:
a second memory cell including a second magnetoresistance effect element, and a second switching element connected to the second magnetoresistance effect element;
a fifth wiring connected to a ninth end of the second memory cell;
a sixth wiring connected to a tenth end of the second memory cell;
a fourth switch including an eleventh end connected to the sixth wiring, and a twelfth end;
a seventh wiring connected to the twelfth end;
a fifth switch including a thirteenth end connected to the seventh wiring, and a fourteenth end connected to the fourth wiring;
a second transistor including a gate connected to the seventh wiring, a fifteenth end connected to the fourth wiring, and a sixteenth end; and
a sixth switch connected between the sixteenth end and a second node that receives the first voltage,
said method further comprising,
during the time period for reading data from the first memory cell:
maintaining the fourth switch, the fifth switch, and the sixth switch to be OFF.

13. The method of claim 11, further comprising:
in a second time period before the first time period, causing the fourth wiring to be electrically floating after a second voltage is applied;
while the fourth wiring is caused to be electrically floating, applying a third voltage lower than the second voltage to the first wiring; and
in the first time period, applying a fourth voltage lower than the third voltage to the first wiring.

14. The method of claim 11, wherein
the time period for reading further includes a third time period that starts during the first time period and ends with the first time period,
said method further comprising, during the third time period:
turning OFF the first switch and then maintaining the first switch to be OFF;
maintaining the second switch to be OFF; and
turning ON the third switch and then maintaining the third switch to be ON.

15. The method of claim 14, wherein
in a second time period before the first time period, causing the fourth wiring to be electrically floating after a second voltage is applied;
while the fourth wiring is caused to be electrically floating, applying a third voltage lower than the second voltage to the first wiring; and
in the first time period, applying a fourth voltage lower than the third voltage to the first wiring.

16. The method of claim 11, wherein
the time period for reading data from the first memory cell further includes a third time period that starts during the first time period and ends with the first time period,
said method further comprising, during the first time period:
turning OFF the first switch and then maintaining the first switch to be OFF until a start of the third time period;
turning ON the first switch at the start of the third time period and then maintaining the first switch to be ON;
maintaining the second switch to be OFF; and
turning ON the third switch and then maintaining the third switch to be ON.

17. The method of claim 16, wherein
in a second time period before the first time period, causing the fourth wiring is caused to be electrically floating after a second voltage is applied;
while the fourth wiring is caused to be electrically floating, applying a third voltage lower than the second voltage to the first wiring; and
in the first time period, applying a fourth voltage lower than the third voltage to the first wiring.

18. The method of claim 11, further comprising:
charging a first capacitor based on a voltage of the fourth wiring;
charging a second capacitor based on a reference voltage; and
comparing a voltage of the first capacitor and a voltage of the second capacitor to determine the data stored in the first memory cell.
